(19) United States
(12) Patent Application Publication
(10) Pub. No.: US 2007/0047359 A1
(43) Pub. Date: Mar. 1, 2007

(54) Flash memory device

(75) Inventors: Jia-Yong He, Kunshan (CN); Qi-Jun Zhao, Kunshan (CN); Mao-Lin Lei, Kunshan (CN); Yu-Long Mao, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/512,908

(22) Filed: Aug. 30, 2006

(30) Foreign Application Priority Data
Aug. 31, 2005 (CN) 200520075196.7

(51) Int. Cl. G11C 7/02

(52) U.S. Cl. 365/207

(57) ABSTRACT

A flash memory device (1) includes a cover (10), a metal shield (20) received in the cover (10), a printed circuit board (6) accommodated in the metal shield (20), a cap member (30) for shielding the front the portion of the metal shield (20) and a latching device for interconnecting the metal shield (20) and the cover (10). The latching device contains a resilient ring (40) containing an opening (43) for the shield (20) to extend therethrough and a fixing device (50) for abutting against the rear edge of the printed circuit board (6). The cap member (30) contains a Y-shaped outer shell (31) and an inner shell (32) retained in the outer shell (31). The metal shield (20) contains a number of through holes (211) and the inner shell (32) contains a number of fingers (321) for mating with the through holes (211).

### BACKGROUND OF THE INVENTION

1. Field of the Invention

The present invention relates to a flash memory device, and more particularly to a portable flash memory device with a universal serial bus (USB) interface.

2. Description of the Prior Art

With the fast development of the electrical domain, flash memory is currently used in variety of apparatus including digital cellular phone, digital camera, PC card, and digital setup box or inner controller for notebook computer. In the meantime, a USB interface plays a role of plug and play between a computer and a flash memory device and the computer could read data stored in the flash memory device through such USB interface or could record necessary data on the flash memory device.

U.S. Pat. No. 6,456,500 B1 issued to Speed Tech Corp., on Sep. 24, 2002 discloses a flash memory device comprising an upper cover, a lower cover opposite the upper cover, a circuit board received in a receiving space formed by the upper and lower covers, a lateral decorative strip provided for reinforcing the connection of the upper and lower covers and a sheath fitted around the upper and lower covers. Besides, an interface is disposed at a front portion of the circuit board for engaging with corresponding electrical equipment. A bolt is passed through complementary holes to combine the upper and lower covers. However, when the conventional flash memory device drops off accidentally, the upper and lower covers easily disengage with each other and the flash memory device might be out of use. Further more, the volume of the flash memory device will become large since the strip is used for combining the bottom and upper covers.

Accordingly, there is a need for providing a flash memory device having a small volume and with a firm and compact structure.

### BRIEF SUMMARY OF THE INVENTION

It is an object of the present invention to provide a flash memory device with a firm and compact structure which can be easily assembled.

In order to attain the objective above, A flash memory device includes a cover defining a chamber, a metal shield received in the chamber, a printed circuit board accommodated in the metal shield, a cap member for shielding the front portion of the metal shield and a latching device for interconnecting the metal shield and the cover. The latching device contains a resilient ring and a fixing device. The metal shield contains a plurality of through holes. Each resilient ring or fixing device contains at least an arm for engaging with corresponding through hole of the metal shield. The resilient ring contains an opening for the shield to extend therethrough and the fixing device abuts against the rear edge of the printed circuit board. The cap member defines a Y-shaped outer shell and an inner shell retained in the outer shell. Said inner shell contains a plurality of fingers for mating with complement through holes of the metal shield for retaining purpose. By means of the metal shield and the cover are respectively molded as a whole manufactured feature so that the assembling procedure is reduced. Meanwhile, the latching device and a cap member are provided to ensure the structure of the flash memory device compact and firm.

Other objects, advantages and novel features of the invention will become more apparent from the following detailed description of the present embodiment when taken in conjunction with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a perspective view of a flash memory device inserting into a cap member according to the present invention;

FIG. 2 is a perspective view of the flash memory device when it is not inserted into the cap member;

FIG. 3 is another perspective view of the FIG. 2 seen from the other side;

FIG. 4 is an partially exploded view of the flash memory device except the cap member;

FIG. 5 is another exploded view of FIG. 4 seen from the other side;

FIG. 6 is an exploded view of the cap member of the present invention; and

FIG. 7 is another exploded view of FIG. 6.

### DETAILED DESCRIPTION OF THE INVENTION

Reference will now be made in detail to the preferred embodiment of the present invention.

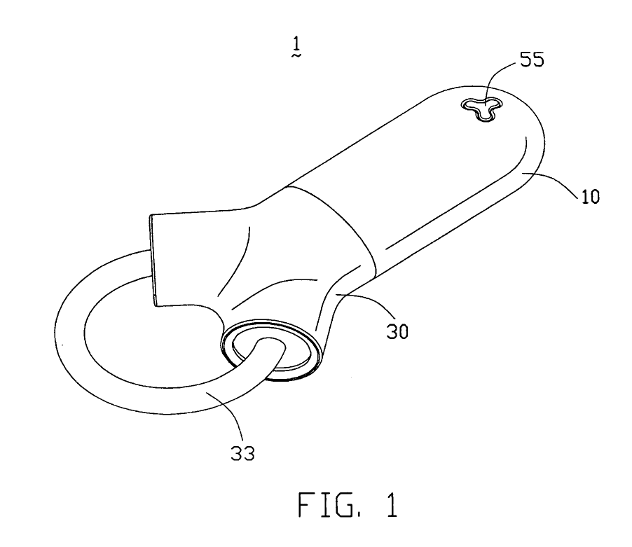

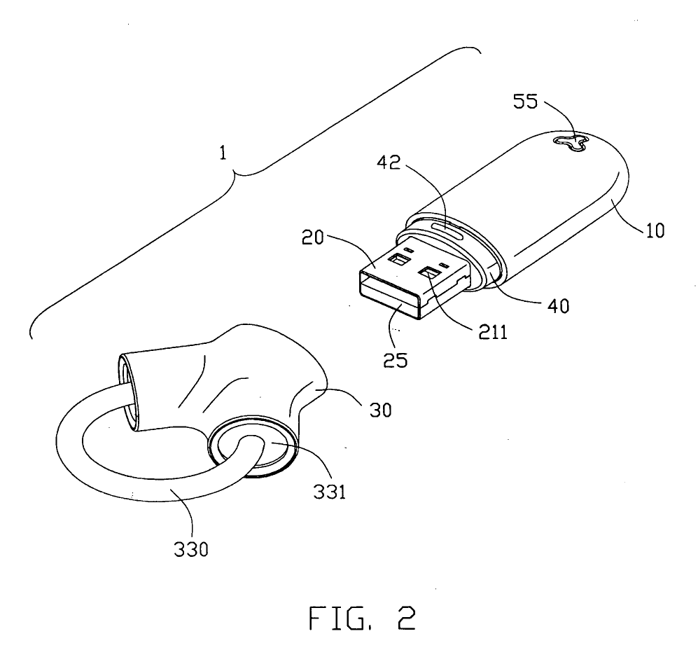

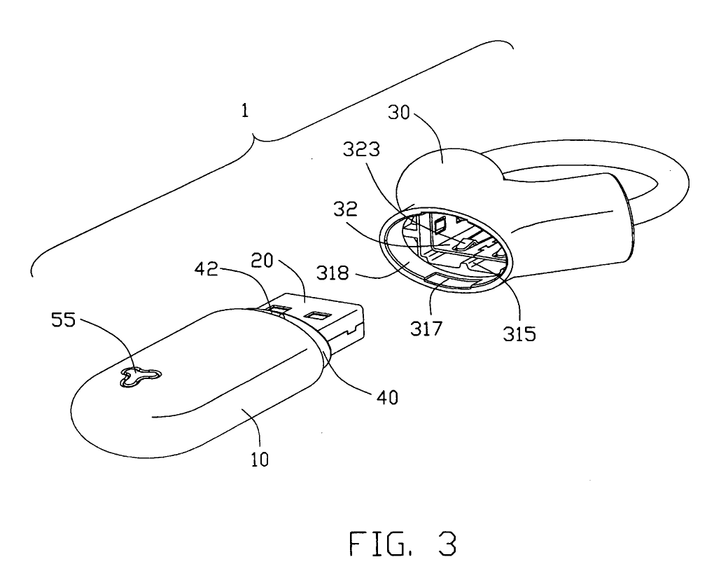

Refer to FIGS. 1-4, a flash memory device 1 according to the present invention includes an elongate cover 10, a metal shield 20 received in the cover 10, a memory unit accommodated in the metal shield 20, a cap member 30 for shielding the front the portion 21 of the metal shield 20, and a latching device for connecting the cover 10 and the metal shield 20. In this embodiment, the memory unit is a printed circuit board (PCB) 6. The latching device contains a resilient ring 40 and a fixing device 50.

The cover 10 defines a chamber 13 for accommodating complementary metal shield 20 therein and a first recess 12 extending through the upper and lower surface (not labeled) at the back of the cover 10. A plurality of flanges 11 are disposed in the inner side of the cover 10 for intervening with the metal shield 20 and mating with the resilient ring 40.

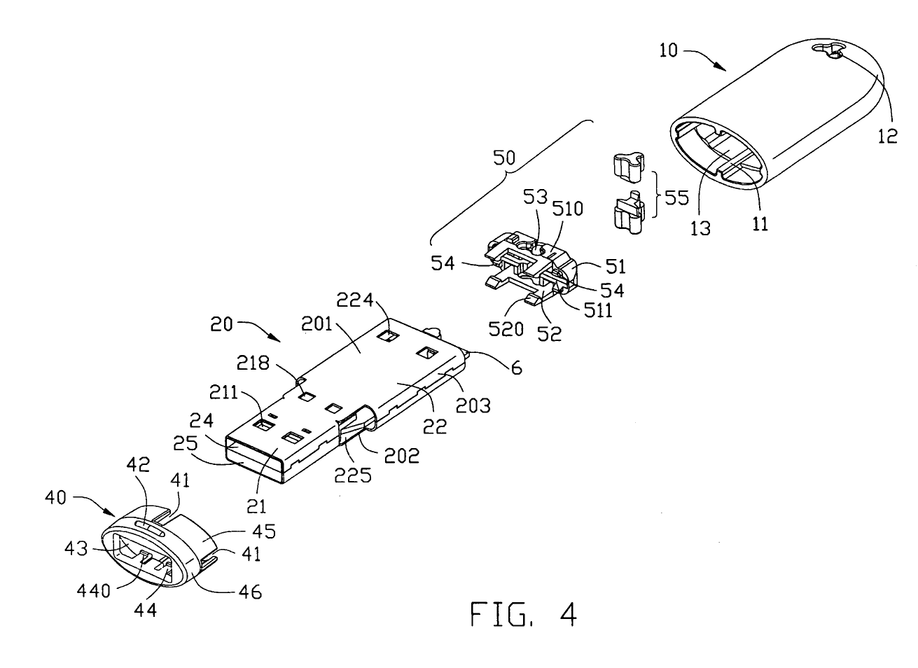

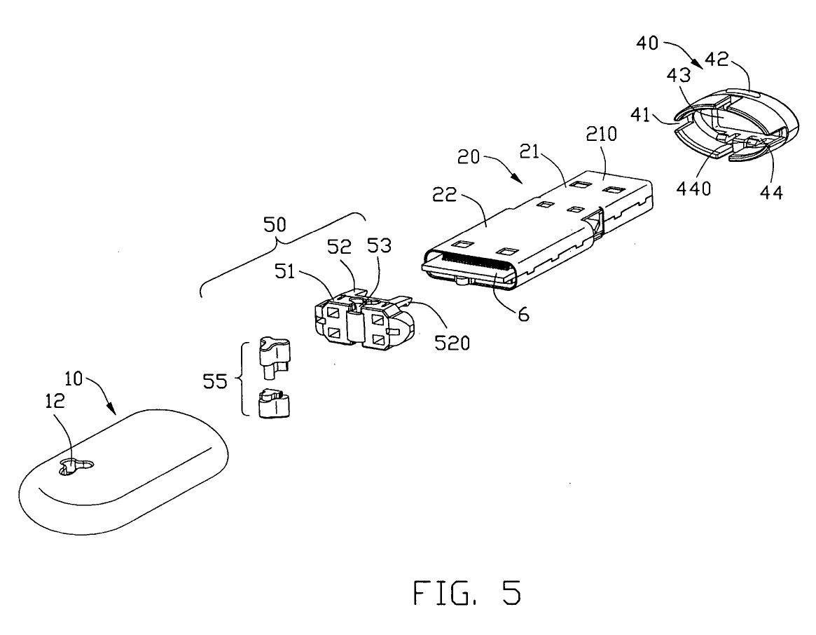

Further refer to FIGS. 4-5, the metal shield 20 is formed by a top wall 201, a bottom wall 202 opposite the top wall 201 and two step-shaped side walls 203 bending from the lateral edges of the top and bottom walls 201, 202 wherein all of the top, bottom and side walls 201, 202, 203 form a hollow cavity 204 for receiving the PCB 6 therein. Both top and bottom walls 201, 202 respectively define three pairs of rectangle-shaped first, second and third through holes 211, 218, 224 along the elongate direction of the metal shield 20. In detail, the first, second and third pairs of through holes 211, 218, 224 are respectively set in the front, midterm, and back section of the top and bottom walls 201, 202. There further defines a pair of slits 225 in the middle section of the side walls 203. The metal shield 20 is divided into a front portion 21 and a rear portion 22. The flash memory device 1 further contains a mating element 25 defining a plurality of contacts (not shown) thereof. The PCB 6 defines a plurality of golden fingers (not shown) electrically connected with the contacts. In assembly, the PCB 6 and the mating element 25 are inserted into the cavity 204 from the rear portion 22 wherein the mating element 25 is received in the front portion 21 and the corresponding part of the PCB 6 is engaging with the slits 225 for resisting purpose. The metal shield 20 together with the mating element 25 and the PCB 6 forms an electrical connector which defines a standard USB plug in a front wherein the first pair of through holes 211 are disposed on the surface of the USB plug. Besides, in other embodiments, the PCB 6 can form a plurality of golden fingers which immediacy form a standard USB plug together with the front portion 21 of the metal shield 20.

The circle-shaped resilient ring 40 comprises a base portion 45 defining a plurality of slots 41 corresponding to the flanges 11 of the cover 10, an enlarged engaging portion 46 extending forwardly from the base portion 45 and an opening 43 extending through the base portion 45 and the engaging portion 46. The engaging portion 46 further contains a couple of gracile protrusions 42 for mating with the cap member 30. The opening 43 contains an upper and a lower surfaces (not labeled) respectively defining a pair of first arms 44 wherein each first arm 44 contains a hook 440 in the free end for engaging with the second through hole 218 of the metal shield 20.

The fixing device 50 is composed of a main body 51 and two pairs of second arms 52 extending forwardly from the upper and lower edges of the main body 51 wherein each second arm 52 defines a barb 520 for mating with the third through hole 224. There is a notch 54 in the front wall 511 of the main body 51 for resisting the back of the PCB 6. The main body 51 defines a second recess 53 corresponding to the first recess 12 of the cover 10 through the upper and lower walls 510. The fixing device 50 further defines a couple of dowels 55 which can be simultaneity inserted into the first and second recess 12, 53 for fixing purpose.

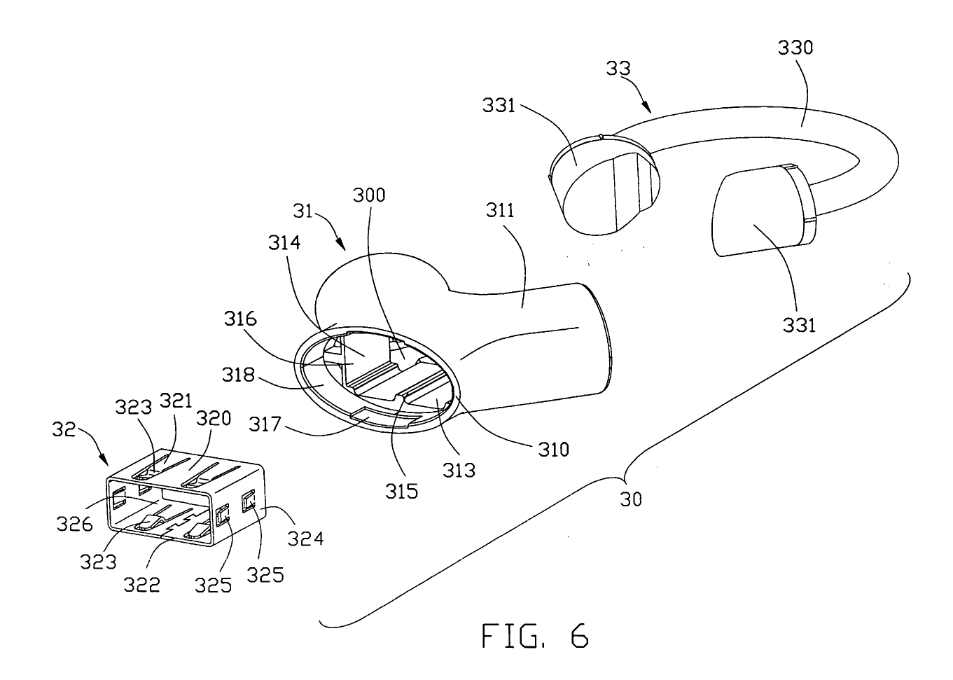

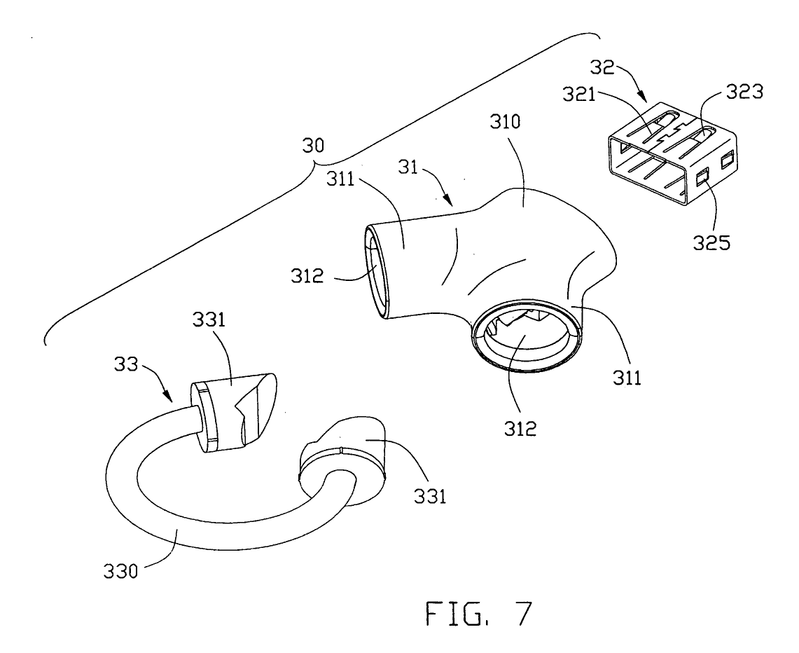

Further refer to FIGS. 6-7, the cap member 30 includes a Y-shaped outer shell 31, a rectangle-shaped inner shell 32 received in the outer shell 31 and a tach 33 connected to the outer shell 31. The outer shell 31 contains a mating portion 310 and a pair of bifurcate distal ends 311 wherein each distal end 311 defines a mounting hole 312. The tach 33 contains a C-shaped middle portion 330, a pair of enlarged portions 331 at the two free ends of the C-shaped middle portion 330 for being inserted into the mounting hole 312 of the outer shell 31. The mating portion 310 further defines a front section 318 and a rear section 314. The front section 318 contains a couple of dents 317 for fitting with the protrusions 42 of the resilient ring 40 and the rear section 314 includes a rectangle-shaped depression 300 formed by two top and bottom walls 313 and a pair of side walls 316 wherein a plurality of ribs 315 are positioned in the two top and bottom walls 313 for abutting against the inner shell 32.

In addition, the inner shell 32 contains a receiving room 326 formed by a top panel 320, a bottom panel 322 opposite the top panel 320 and a pair of side panels 324. Both of the side panels 324 define a pair of barbs 325 extending out of the receiving room 326. Each top panel 320 or bottom panel 322 defines a couple of resilient fingers 321 wherein each finger 321 contains a raised portion 323 extending into the receiving room 326 for engaging with the front portion 21 of the metal shield 20.

In assembly, firstly, insert the PCB 6 and the mating element 25 into the cavity 204 from the rear portion 22 of the metal shield 20 wherein the corresponding part of the PCB 6 is engaging with the slits 225 for resisting purpose and the golden fingers (not labeled) in the front of the PCB 6 are fitting with the mating element 25. The front portion 21 together with the mating element 25 and the golden fingers forms a standard USB interface. Secondly, the fixing device 50 is mounted to the metal shield 20 and abuts against the PCB 6 wherein the back portion of the PCB 6 is received in the notch 54 of the front wall 511 and the barbs 520 of the second arms 52 are engaging with the third through holes 224 of the metal shield 20. Then, put the mental shield 20 through the opening 43 of the resilient ring 40 wherein the hooks 440 of the first arms 44 are engaging with the second through holes 218 of the metal shield 20. Under this condition, the fixing device 50 and the resilient ring 40 are fastened to the metal shield 20 to become an integer. Successively, put the integer into the chamber 13 of the cover 10 wherein the resilient ring 40 and the fixing device 50 are both engaging with the cover 10. The second recess 53 of the fixing device 50 are corresponding to the first recess 12 of the cover 10. The flanges 11 of the cover 10 are inserted into the slots 41 of the base portion 45 of the resilient ring 40. The engaging portion 46 is positioned outside of the chamber 13 for connecting to the cap member 30. The USB plug is protruding out of the engaging portion 46 of the resilient ring 40 to be inserted into the cap member 30 for protection purpose.

The cap member 30 is assembled as follows: first of all, insert a pair of enlarged portions 331 into corresponding mounting holes 312 of the outer shell 31. Then, put the inner shell 32 into the depression 300 of the outer shell 31 wherein the barbs 325 of the side panels 324 are intervening with the rear section 314 of the outer shell 31.

When not in use, the USB plug can be inserted in the receiving room 326 of the inner shell 32 wherein the raised portions 323 are engaging in the first through holes 211 of the front portion 21 of the metal shield 20 and the protrusions 42 of the resilient ring 40 are engaging in the dents 317 formed in the front section 318 of the outer shell 31.

Comparing with the prior art, the metal shield 20 is molded as a whole manufactured feature so that the assembling procedure is reduced. Besides, a fixing device 50 is provided for resisting the PCB 6 after which is inserted in the metal shield 20. In addition, a resilient ring 40 is set for connecting the metal shield 20 with the cover 10. Further more, a cap member 30 is provided for protecting the USB plug and beautify the prevent invention. As a result, the predetermined structure of the present invention is compact and firm to prevent the flash memory device 1 from disengaging or departing when it drops off accidentally.

Although the invention has been described with respect to certain preferred embodiments, those skilled in the art will recognize that changes could be made without departing from the spirit and scope of the invention. For example, the engaging portion 46 of the resilient ring 40 can contain a couple of dents and the mating portion 310 can define multiple protrusions for engaging with the dents. Also, the front wall 511 of the main body 51 can set at least a couple of projectings defining a slot therein for resisting the back of the PCB 6. Accordingly, it is appropriate that the appended claims be construed broadly and in a manner consistent with the scope of the invention.

What is claimed is:

1. A flash memory device, comprising:
a cover having a chamber;
a shield received in the chamber of the cover;
a printed circuit board surrounded by the shield with an interface formed thereon; and
a latching device mounted on the shield and mechanically interconnecting the shield and the cover.

2. The flash memory device according to claim 1, wherein the latching device defines an arm and said shield comprises an aperture for engaging with said arm.

3. The flash memory device according to claim 2, wherein the shield defines a top wall and a bottom wall, the arm defining a barb adapted for engaging with the aperture from the top wall or the bottom wall.

4. The flash memory device according to claim 1, wherein the latching device defines a notch for receiving a rear edge of the printed circuit board.

5. The flash memory device according to claim 1, wherein the latching device defines a recess and a dowel, and the cover defines therethrough a hole corresponding to the recess, and wherein the dowel is inserted in the recess through the hole to thereby interconnect the latching device and the cover.

6. The flash memory device according to claim 1, wherein the interface meets a USB interface standard.

7. The flash memory device according to claim 1, wherein the latching device is detachably mounted on the shield and defines an opening with the interface extending therethrough.

8. The flash memory device according to claim 7, wherein said shield comprises an aperture and the latching device defines an arm comprising a hook for engaging with said aperture.

9. The flash memory device according to claim 7, wherein the latching device defines a base portion and an engaging portion extending from the base portion, the base portion defining a slot and the cover comprising a flange for mating with the slot.

10. A portable memory device assembly, comprising:
an electrical connector defining an interface, a memory unit and a shield covering said memory unit; and
a cap member defining an outer shell and an inner shell retained in the outer shell, said inner shell enclosing the interface and lockable with the shield of the connector.

11. The portable memory device assembly according to claim 10, wherein the outer shell defines a depression for accommodating the inner shell which is configured to the interface.

12. The portable memory device assembly according to claim 10, wherein the inner shell defines a receiving space which is vacant for accommodating the interface.

13. The portable memory device assembly according to claim 12, wherein the receiving space is formed by a top panel, a bottom panel and two side panels, said inner shell comprising a finger with a raised portion extending into the receiving space, the shield comprising a depression for engaging with the raised portion.

14. The portable memory device assembly according to claim 10, wherein the outer shell is Y-shaped and defines a pair of mounting holes disposed in the two bifurcate distal ends thereof, and wherein the cap member comprises a tach for mating within the mounting holes.

15. The portable memory device assembly according to claim 10, further comprising a cover enclosing said connector with the interface exposed to the cover.

16. The portable memory device assembly according to claim 16, further comprising a ring which defines a base portion received in the cover, an engaging portion for mating with the cap member and an opening with the connector extending therethrough.

17. The portable memory device assembly according to claim 15, further comprising a fixing device retained on the shield wherein the fixing device defines a recess and a dowel, the cover defining therethrough a hole corresponding to the recess, and wherein the dowel is inserted in the recess through the hole to thereby interconnect the fixing device and the cover.

18. A portable memory device comprising:
a frame like metallic shell enclosing a printed circuit board and a mating port; and
a circumferential rear cover and a circumferential front ring attached to each other in an axial direction and commonly circumferentially enclosing the shell therein; wherein
at least one of said rear cover and said front ring is directly latched to the shell.

19. The portable memory device as claimed in claim 18, wherein the other of said rear cover and said front ring is indirectly connected to the shell via a latching device.

20. The portable memory device as claimed in claim 18, further including means for aligning the rear cover and the front ring together during assembling.
